(19) United States
(12) Patent Application Publication
(10) Pub. No.: US 2011/0067908 A1
(43) Pub. Date: Mar. 24, 2011

(54) METHOD FOR PRODUCING A PRINTED CIRCUIT BOARD AND USE AND PRINTED CIRCUIT BOARD

(76) Inventors: Günther Weichslberger, Graz (AT); Johannes Stahr, St. Lorenzen (AT)

(21) Appl. No.: 12/736,916

(22) PCT Filed: May 20, 2009
(86) PCT No.: PCT/AT2009/000210

§ 371 Date: Nov. 22, 2010

(30) Foreign Application Priority Data
May 21, 2008 (AT) GM 293/2008

(51) Int. Cl. H05K 1/09; H05K 3/30

(52) U.S. Cl. 174/257; 29/832

(57) ABSTRACT

The invention relates to a method for fixing a component (6) to or in a printed circuit board (1) and/or for connecting individual elements of a printed circuit board, wherein regions of a component (6) and/or of a printed circuit board (1) to be interconnected or to be fixed to one another are provided with at least one respective solder layer (4, 5, 9, 10), the solder layers (4, 5, 9, 10) are contacted with each other and are interconnected at a pressure and a temperature that is elevated above ambient conditions, an intermetallic diffusion layer (12) being formed, thereby achieving a high-strength connection. The invention further relates to the use of said method and to a printed circuit board (1).

This is a national stage of PCT/AT2009/000210 filed May 20, 2009 and published in German, which has a priority of Austria no. GM 293/2008 filed May 21, 2008, hereby incorporated by reference.

### FIELD OF THE INVENTION

The present invention relates to a method for fixing a component to or in a printed circuit board and/or for connecting individual elements of a printed circuit board as well as the use of such a method and a printed circuit board.

### PRIOR ART

In the context of the production of a printed circuit board and, in particular, the fixation of components to or in a printed circuit board and/or the connection of individual elements of a printed circuit board, for instance in the production of a rigid-flexible printed circuit board, three methods are, above all, applied according to the current prior art, in which context reference is, in particular, made to wire-bonding, soldering and bonding by electrically conducting or conductive adhesive films or adhesives. For the production of rigid-flexible printed circuit boards, plug-in systems requiring plenty of space are further known.

In wire-bonding, a wire formed, e.g., of gold or aluminium is connected with a contact pad or contact site of an electronic component by supplying ultrasound, heat and pressure and is subsequently drawn onto a contact surface or region to be connected therewith, on a printed circuit board where the connecting or bonding procedure using, e.g., ultrasound, heat and/or pressure is repeated. Besides the high costs involved in such a bonding process, the main disadvantages reside in the sequential succession of the production of individual connections such that no parallel process can be performed and, in particular, every contact or every region to be contacted must be separately produced, thus overall resulting in an expensive method. Due to the types of metal wire used, a partially high thermal load will, moreover, be exerted on the components or elements to be connected or bonded at temperatures of, for instance, up to about 300° C. and optionally even more, whereby a purely average and in most cases insufficient tensile strength of the wire-bond connection will additionally be obtained.

In a soldering process, the application of solder paste deposits is, for instance, followed by the arrangement of components, or elements or subregions of a printed circuit board to be interconnected, on the provided solder paste deposits or sites, whereupon a connection by melting of the solder paste is subsequently effected by heating in a reflow furnace of the entire assembly comprised of, for instance, the components and a substrate of a printed circuit board subregion to be connected therewith. To this end, particularly with lead-free soldering, temperatures of above 240° C. and, in particular, above 265° C. are required at least for a short time, which would constitute a considerable load on the printed circuit board or printed circuit board subregions to be connected with the components and might lead to the separation of individual printed circuit board layers, or delamination.

When using electrically conducting or conductive adhesive films or adhesives, a compromise must, for instance, be found because of the interaction between the filler content of the electrically conducting components, which is relevant to an achievable conductivity, and in view of the adhesive strength to be achieved such that it will, as a rule, only be possible to achieve a limited conductivity without adversely affecting the bonding property. When heating bonded elements comprised of, for instance, a component, or a plurality of electronic components, on a printed circuit board, differently strong dimensional changes will, moreover, occur as a function of the materials used, wherein, in particular, partially strong differences in the expansion coefficients of, for instance, ceramics, which are used in the case of passive components, silicon in the case of active components as well as the synthetics used for adhesive films and adhesives and, for instance, even copper will occur in the region of conductive contact sites or pads and conductor tracks of the printed circuit board such that impairments and destructions of the pads or contact areas provided by the aid of conducting adhesives may be caused by temperature fluctuations or loads due to temperature variations.

### SUMMARY OF THE INVENTION

Departing from a method of the initially defined kind, the present invention, therefore, aims to avoid the above-mentioned drawbacks in respect to the problems of maintaining a proper bonding and fixation of a component to or in a printed circuit board and/or connection of individual elements of a printed circuit board, and, in particular, provide a resistant and an improved or enhanced tensile strength-exhibiting connection or fixation of at least one component to or in a printed circuit board, and/or between individual elements of a printed circuit board, as well as a printed circuit board with an improved adherence of individual components and/or subregions.

To solve these objects, a method of the initially defined kind is essentially characterized in that regions of a component and/or a printed circuit board to be interconnected or fixed to one another are provided with at least one respective solder layer, that the solder layers are contacted with each other and interconnected at a pressure and a temperature that are elevated relative to ambient conditions, with an intermetallic diffusion layer being formed. Since, after having applied at least one respective solder layer on regions of a component and a printed circuit board, or subregions or subelements of a printed circuit board, which are to be interconnected or fixed to one another, the solder layers are mutually bonded and interconnected by applying a pressure and temperature elevated relative to ambient conditions while forming an intermetallic diffusion layer, a proper and high-strength connection between the components and/or elements of a printed circuit board, which are to be connected with, or fixed to, one another will be ensured while forming alloys or connections between the mutually adjoining or bonded solder layers, whereby elevated tensile strengths as well as improved resistances against destruction, particularly during use, for instance, under varying temperature conditions or stresses will be achieved as compared to known methods. By forming an intermetallic diffusion layer for connecting regions to be interconnected or fixed to one another, particularly pads, of a component as well as elements of a printed circuit board, an approximation or coordination of, for instance, the thermal expansion coefficients of the used materials will be obtained so as to enable the achievement of a strongly improved resistance against impairment or destruction of the connection even at fluctuating temperature stresses, by an adaptation or homogenization of the expansion coefficients of the materials used to provide the connection. The fixing or connecting procedure, moreover, ensures that both the components to be arranged or fixed and the printed circuit board, or the printed circuit board subregions to be bonded or connected, for instance, of a rigid-flexible or stiff-flexible printed circuit board will be exposed to a more uniform and, in particular, lower thermal load as compared, for instance, to a known solder-bonding or wire-bonding process. The use of a diffusion-soldering method or melt-diffusion soldering method while applying a pressure and temperature that are elevated relative to ambient conditions for forming the intermetallic diffusion layer causes the materials or components of the mutually bonded solder layers to diffuse into one another so as to provide a high-strength connection by the diffusion of the solder layers into one another or with one another. In doing so, intermetallic phases or alloys can occur or be produced between the materials used for the formation of the intermetallic diffusion layer, wherein it has to be taken care that such a diffusion of the materials into one another takes place at temperatures which are far below the melting temperatures of the raw materials respectively used for the solder layers, as will be discussed in more detail below.

To carry out the diffusion-soldering method at pressure and temperature conditions to which even subregions of a printed circuit board can be exposed without impairment, while simultaneously achieving a proper connection or fixation by diffusion, of the materials used for the respective solder layer or layers, it is proposed according to a preferred embodiment of the method according to the invention that the at least one solder layer is formed by an electrically conducting metal selected from the group comprising silver, gold, nickel and copper and/or tin, indium and bismuth. The mentioned materials exhibit the good and high electrical conductivities required to achieve proper bonding between the regions or contact sites of a component and/or printed circuit board to be connected and, moreover, ensure that, particularly at a relatively low temperature and an appropriate pressure over an appropriate period of time, a reliable intermetallic connection will be formed between the solder layers of the components or elements to be connected.

In order to prevent the materials used for the formation of the intermetallic diffusion layer as a solder connection from diffusing into the pads or contact areas of the components or elements to be interconnected or fixed to one another, it is proposed according to a further preferred embodiment that, prior to applying the at least one solder layer, a barrier layer is applied to the regions to be interconnected or fixed to one another, of a component and/or a printed circuit board. This barrier layer will prevent the solder materials or elements of the forming intermetallic connection, or optionally formed alloy, from diffusing into the region of the regions or pads to be interconnected or fixed to one another, of the component and/or printed circuit board.

To ensure the reliable formation of a barrier layer while simultaneously maintaining sufficient conductivity as well as a reliable connection to the adjoining regions or pads of the components and elements to be interconnected or fixed to one another as well as the at least one solder layer to be provided in addition, it is proposed according to a further preferred embodiment that the barrier layer is formed by an electrically conducting metal selected from the group comprising nickel, iron or molybdenum and/or alloys containing nickel and/or iron.

To support the melt-diffusion procedure for connecting the regions to be interconnected or fixed to one another, particularly pads, it is proposed according to a further preferred embodiment that two different solder layers are each applied on a region to be connected or fixed. By providing or applying two different solder layers, it is, for instance, possible to selectively initiate or start the diffusion procedure after having contacted the regions to be interconnected, by appropriately selecting the immediately adjacent solder layers, while controlling the progressing or continuing bonding under the formation of an intermetallic diffusion layer by providing a further solder layer. In this respect, the different solder layers can, for instance, be selected in terms of melting temperature, wherein, for instance, a solder layer of a low-melting-temperature material is each fixed to the upper sides of the regions to be interconnected, on which a solder layer of a higher-melting-temperature material with optionally an improved or enhanced electrical conductivity is subsequently applied such that, for instance, an eutectic alloy of the materials used for the solder layers is additionally formed during the diffusion procedure, exhibiting an accordingly high resistance against destruction of the connection as well as an accordingly high and good electrical conductivity of the bonding to be achieved.

For a particularly reliable and simple application of the respective at least one solder layer in the small thickness or layer thickness particularly linked to the production of a printed circuit board, it is proposed according to a further preferred embodiment of the method according to the invention that the at least one solder layer and the barrier layer are electrochemically or chemically deposited or applied.

In the context of the production of a printed circuit board in which, with an increasing miniaturization of the same, accordingly small layer thicknesses of the individual elements are used, and in consideration of the achievement of an accordingly resistant connection or bond, it is proposed according to a further preferred embodiment that the at least one solder layer and/or the barrier layer have a thickness of at least 5 nm, in particular at least 100 nm to at most 100 μm, preferably at most 20 μm. Such layer thicknesses of the solder layer(s) and/or barrier layer to be employed range within layer thicknesses usually applied in the production of printed circuit boards to individual elements or layers of such printed circuit boards, so that the bondings to be produced can be readily integrated in such printed circuit boards.

In order to achieve a reliable connection of the regions or elements to be bonded while forming an intermetallic diffusion layer, it is proposed according to a further preferred embodiment that the soldering procedure is carried out at a pressure of less than 300 bar, in particular less than 250 bar, and at temperatures of below 600° C., in particular between 150° C. and 450° C. Under special consideration of the temperatures used for the melt-diffusion soldering procedure, it is immediately apparent that the soldering procedure is performed at temperatures partially lying considerably beyond the melting temperatures of the materials used for forming the solder layers.

For the formation of the intermetallic diffusion layer during the connecting or fixing procedure, it is proposed according to a further preferred embodiment that the elevated pressure and the elevated temperature are applied for a period of at least 10 minutes, in particular at least 20 minutes and at most 150 minutes, in particular at most 120 minutes.

In the context of the connecting or fixing method according to the invention, it should be additionally noted that a plurality of connections or fixations can be simultaneously realized after the application of the respective at least one solder layer and the mutual bonding of the solder layers such that, as opposed to known techniques like soldering or wire-bonding, a parallel or simultaneous execution of a connecting or fixing procedure can be effected for an optionally extremely large number of regions, particularly pads, to be interconnected or fixed to one another.

In order to ensure an optionally required temporary or provisional positioning of a component to be fixed, or elements of a printed circuit board to be fixed to one another, after the application of at least one solder layer and optionally the barrier layer as well as the bonding of the solder layers of the elements or components to be connected, it is proposed according to a further preferred embodiment of the method according to the invention that a component to be fixed, or elements to be fixed to one another, of a printed circuit board are temporarily connected with one another using an adhesive layer. Since the fixation by adhesion is merely provided for temporary positioning before and after the execution of the melt-diffusion method for forming the connections or fixations, adhesives satisfying accordingly simple and only minor demands in terms of adhesive strength will do, since the connection or bonding to be finally achieved is effected subsequently during the diffusion method for fixing the components or elements to or with one another, which is performed at a pressure and temperature that are elevated relative to ambient conditions.

As already mentioned above several times, the method according to the invention in a particularly preferred manner can, for instance, be used for loading electronic components onto or into a printed circuit board, such components comprising active or passive components, single components or assemblies.

The method according to the invention in a preferred manner can, moreover, be applied or used for connecting printed circuit board segments or elements, in particular, for the production of a rigid-flexible printed circuit board.

Another preferred field of application or use of the method according to the invention resides in the production or formation of heat-dissipating elements in or on a printed circuit board, wherein it is possible, by arranging solder layers of appropriate materials, to produce such heat-dissipating elements, for instance, simultaneously with the production of a connection or fixation of components to or in a printed circuit board, or a connection of individual elements of a printed circuit board to one another.

To solve the initially defined objects, a printed circuit board is moreover provided, which is essentially characterized in that regions to be interconnected or fixed to one another, of a component and/or a printed circuit board are each provided with at least one solder layer, that the solder layers are contactable with one another and interconnectible with one another at a pressure and a temperature that are elevated relative to ambient conditions, with an intermetallic diffusion layer being formed. Due to the formation of an intermetallic diffusion layer between regions to be connected or contacted, for instance contact pads, a printed circuit board will thus be provided, in which components or elements to be interconnected are fixed to, or connected with, one another, exhibiting a highly reliable connection or bond.

### SHORT DESCRIPTION OF THE DRAWINGS

In the following, the invention will be explained in more detail by way of exemplary embodiments schematically illustrated in the attached drawing. Therein:

FIG. 1 is a schematic illustration of a subregion of a printed circuit board according to the invention as well as a component separated therefrom and hence to be connected therewith, wherein a barrier layer and two solder layers have already been deposited by the method according to the invention in the region of regions to be interconnected;

FIG. 1A is a detailed view of subregion A of FIG. 1 on an enlarged scale;

FIG. 2, in an illustration similar to that of FIG. 1, is a detailed view of the printed circuit board with adhesion sites for the temporary positioning of the components to be connected with the printed circuit board;

FIG. 3 depicts the component arranged on the printed circuit board by the aid of the adhesive applied according to FIG. 2, prior to carrying out the melt-diffusion method;

FIG. 4 depicts the component fixed to the printed circuit board after having carried out the melt-diffusion method under the formation of an intermetallic diffusion layer between the solder layers; and

FIG. 5, in an illustration similar to that of FIG. 1, shows elements to be interconnected, of an, in particular, rigid-flexible printed circuit board prior to their interconnection and after the application of a solder layer on the regions to be interconnected.

### DETAILED DESCRIPTION OF PREFERRED EMBODIMENTS

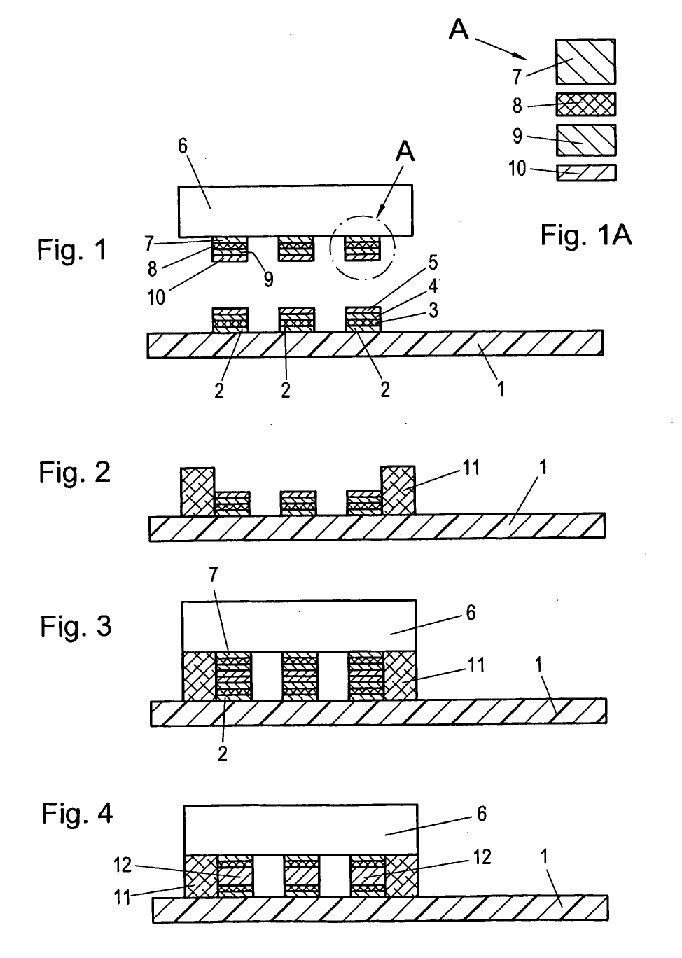

FIGS. 1 to 4 depict different method steps in the performance of the method for fixing a component to or in a printed circuit board.

In FIG. 1 it is shown that, on a printed circuit board generally denoted by 1, in the region of contact pads each denoted by 2 and, for instance, made of copper, a barrier layer 3 is arranged on this copper layer 2, on which barrier layer two layers 4 and 5 of different solder materials are subsequently arranged or applied.

In a similar manner, a barrier layer 8 is each arranged or applied on an electronic component 6 to be connected with the printed circuit board 1 in the region of contact sites or pads 7, on which solder layers 9 and 10 of different materials are again subsequently applied or provided.

FIG. 1A depicts the subregion A of the component 6 according to FIG. 1 on an enlarged scale, wherein it is apparent that, on the contact layer 7, which is illustrated with an exaggerated thickness, a barrier layer 8 is subsequently provided, on which the solder layers 9 and 10 are subsequently further applied.

In the illustration according to FIG. 1A, the individual layers 7 to 10 are depicted in a slightly separated manner for the sake of clarity, such a separation merely serving to simplify the clarity of the graphic illustration. Moreover, the thicknesses of the individual layers 7 to 10 are merely exemplary and not to scale, possibly usable layer thickness ranges being discussed in more detail below.

The regions of the pads 2 of the printed circuit board 1 are also formed in a manner similar to the illustration according to FIG. 1A, so that it may be anticipated that, in the embodiment illustrated in FIG. 1, the layers or contact sites 2 and 7 are each formed by copper, whereupon barrier layers 3 and 8 made, for instance, of nickel are respectively applied subsequently. The solder layers 4 and 9 and 10, respectively, which are to be connected with each other, in the exemplary embodiment depicted in FIG. 1 may, for instance, each be made of silver for layers 4 and 9, and of tin for layers 5 and 10.

The application of the layers 3, 4 and 5 and 8, 9 and 10, respectively, can be effected by electrochemical or chemical deposition or application.

After the arrangement or application of the barrier layer 3 as well as the at least one solder layer 4 and 5 in the region of the contact pads 2 on the printed circuit board 1, the arrangement or application of adhesion sites or layers 11 takes place as illustrated in FIG. 2, via which a temporary fixation or arrangement of the component 6 is subsequently effected as illustrated in FIG. 3, wherein it is apparent from FIG. 3 that bonding of the solder layers is effected subsequently, thus causing, in particular, the mutually facing layers 5 and 10 to immediately contact each other.

The arrangement of the component 6 on the printed circuit board 1, particularly by the aid of adhesion sites 11, is followed by the application of a pressure and temperature elevated relative to ambient conditions so as to form an intermetallic diffusion layer 12, wherein, if silver is used for the layers 3 and 9 and tin is used for the layer 5 and 10, said diffusion layer 12 will be formed by an eutectic silver-tin alloy, which, as compared, for instance, to known connections between contact sites of a component 6 and a printed circuit board 1, will have an elevated tensile strength of, for instance, larger than 1000 N/m².

The thickness of the barrier layers 3 and 8, respectively, in this case ranges between 100 nm and 20 μm. The thickness of the solder layers 4 and 5 and 9 and 10, respectively, ranges from about 100 nm to a maximum of 100 μm.

After having contacted the solder layers as indicated above, a pressure and a temperature elevated relative to ambient conditions are applied, as indicated above, wherein, for the materials selected in FIGS. 1 to 4, a period of, for instance, at least 15 minutes and, in particular, about 20 to 120 minutes is chosen, with a pressure of less than 250 bar and, in particular, as a function of the material used for the printed circuit board 1 as well as the component 6, temperatures of between 150° C. and 450° C. being selected, which may optionally also referred to as soft-soldering.

For the barrier layers 3 and 8, nickel may, for instance, be replaced with iron or molybdenum and/or alloys containing nickel and/or iron.

For the soldering layers 4 and 5 as well as 9 and 10, materials or metals having different melting points may, in particular, be used, wherein the adjacent layers 5 and 10 are formed by a metal having a lower melting point and hence higher meltability, while the layers 4 and 9 are, for instance, formed by materials and, in particular, metals having, for instance, generally elevated conductivities, such as e.g. gold or copper instead of silver.

The selection of the materials used for the layers 4 and 5 as well as 9 and 10, moreover, is also performed in view of the alloys to be obtained through melt-diffusion by applying the appropriate temperature and pressure conditions, which alloys will then provide the high-strength and, in particular, high-tensile-stress bond or connection sought.

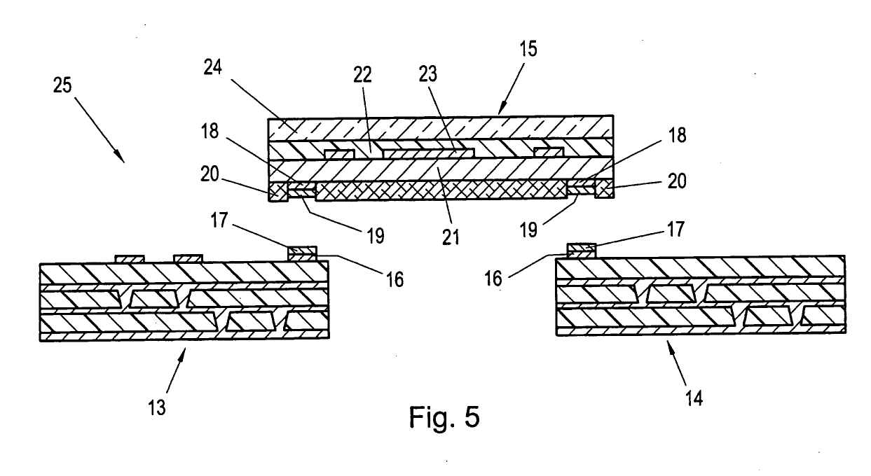

FIG. 5, in a manner similar to FIG. 1, depicts an embodiment in which the method for connecting while forming an intermetallic diffusion layer is used to connect individual elements of a printed circuit board. In this case, rigid parts or elements of a rigid-flexible printed circuit board to be produced are denoted by 13 and 14 in FIG. 5, each consisting of a plurality of layers as generally known.

In the region of connection with a flexible part or element of the rigid-flexible printed circuit board 25 to be produced, pads 16 are arranged or indicated, wherein a solder layer 17 is each arranged or applied on the pads 16, which, for instance, are again made of copper. In a similar manner, a solder layer 19 is again each arranged on the flexible element in the region of pads 18, which may again be formed by copper.

For the temporary positioning of the elements 13, 14 and 15, adhesion sites or zones 20 are provided similarly as in the previous embodiment.

After having applied the soldering layers 17 and 19, bonding of the solder layers 17, 19 is effected similarly as in the embodiment according to FIGS. 1 to 4, whereupon an intermetallic diffusion layer is again formed in the region of the solder layers 17 and 19 by applying a pressure and a temperature elevated relative to ambient conditions, said intermetallic diffusion layer providing a high-strength and accordingly resistant connection of the rigid subregions 13 and 14 with the flexible subregion 15 while forming a plurality of connection or contact sites.

The flexible element 15 in this case is, for instance, comprised of a flexible core 21, above which a prepreg 22 including conductor tracks and bonds 23 is arranged, with a shielding layer being additionally indicated by 24.

Also in this case, a firm connection is formed between the individual regions of the pads 16 and 18 by a melt diffusion process while applying a temperature below the melting temperature for the solder materials 17 and 19.

The above-mentioned materials may again be used as materials for the solder layers 17 and 19.

Moreover, the melt-diffusion method may be applied to form thermally conductive regions for the dissipation of heat possibly forming here and there, in particular, in the region of components 6 integrated in a printed circuit board 1.

1-14. (canceled)

15. A method for fixing a component to or in a printed circuit board and/or for connecting individual elements of a printed circuit board, wherein regions of a component and/or a printed circuit board to be interconnected or fixed to one another are provided with at least one respective solder layer, the solder layers are contacted with each other and connected at a pressure and a temperature that are elevated relative to ambient conditions, wherein the solder layers are interconnected, with an intermetallic diffusion layer being formed.

16. The method according to claim 15, wherein the at least one solder layer is formed by an electrically conducting metal selected from the group comprising silver, gold, nickel and copper and/or tin, indium and bismuth.

17. The method according to claim 15, wherein, prior to applying the at least one solder layer, a barrier layer is applied to the regions to be interconnected or fixed to one another, of a component and/or a printed circuit board.

18. The method according to claim 17, wherein the barrier layer is formed by an electrically conducting metal selected from the group comprising nickel, iron or molybdenum and/or alloys containing nickel and/or iron.

19. The method according to claim 15, wherein two different solder layers are each applied on a region to be connected or fixed.

20. The method according to claim 15, wherein at least one solder layer and/or the barrier layer are electrochemically or chemically deposited or applied.

21. The method according to claim 15, wherein the at least one solder layer and/or the barrier layer have a thickness of at least 5 nm, in particular at least 100 nm to at most 100 μm, preferably at most 20 μm.

22. The method according to claim 15, wherein the soldering procedure is carried out at a pressure of less than 300 bar, in particular less than 250 bar, and at temperatures of below 600° C., in particular between 150° C. and 450° C.

23. The method according to claim 15, wherein the elevated pressure and the elevated temperature are applied for a period of at least 10 minutes, in particular at least 20 minutes and at most 150 minutes, in particular at most 120 minutes.

24. The method according to claim 15, wherein a component to be fixed, or elements to be fixed to one another, of a printed circuit board are temporarily connected with one another using an adhesive layer.

25. The use of a method according to claim 15 for loading electronic components onto or into a printed circuit board.

26. The use of a method according to claim 15 for connecting printed circuit board segments, in particular, for the production of a rigid-flexible printed circuit board.

27. The use of a method according to claim 15 for the production of heat-dissipating elements in or on a printed circuit board.

28. A printed circuit board, wherein regions to be interconnected or fixed to one another, of a component and/or a printed circuit board are each provided with at least one solder layer, the solder layers are contactable with each other and interconnectible with one another at a pressure and a temperature that are elevated relative to ambient conditions, wherein the solder layers are interconnectible, with an intermetallic diffusion layer being formed.
